(19) United States
(12) Patent Application Publication
(10) Pub. No.: US 2026/0040772 A1
(43) Pub. Date: Feb. 5, 2026

(54) DISPLAY DEVICE

(71) Applicant: Japan Display Inc., Tokyo (JP)

(72) Inventors: Tomokazu ISHIKAWA, Tokyo (JP); Ryota TAKASAKI, Tokyo (JP); Yozo NAKAYASU, Tokyo (JP); Sho YANAGISAWA, Tokyo (JP)

(73) Assignee: Japan Display Inc., Tokyo (JP)

(21) Appl. No.: 19/286,249

(22) Filed: Jul. 31, 2025

(30) Foreign Application Priority Data
Jul. 31, 2024 (JP) 2024-124584

(51) Int. Cl. H10K 59/122; H10K 59/80; H10K 59/88

(52) U.S. Cl. CPC H10K 59/122; H10K 59/871; H10K 59/88

(57) ABSTRACT

According to one embodiment, a display device includes a substrate having a display area, pixels in the display area and each including a lower electrode, an upper electrode, and an organic layer between the lower and upper electrodes, a dummy pixel area surrounding the display area and including dummy pixels, and a partition provided in the display area, the dummy pixel area and an outer circumference area surrounding the dummy pixel area, the partition including a lower portion and an upper portion. Further, the partition has slits provided in the display area and the dummy pixel area. The slits are not provided at a boundary between the dummy pixel area and the outer circumference area.

### CROSS-REFERENCE TO RELATED APPLICATION

This application is based upon and claims the benefit of priority from Japanese Patent Application No. 2024-124584, filed Jul. 31, 2024, the entire contents of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device according to the first embodiment.

FIG. 2 is a schematic plan view showing an example of a layout of subpixels of the first embodiment.

FIG. 3 is a schematic cross-sectional view of the display device along the III-III line of FIG. 2.

FIG. 4 is a schematic plan view of the display device according to the first embodiment.

FIG. 5 is a schematic cross-sectional view of a surrounding area of the display device according to the first embodiment.

FIG. 6 is a schematic plan view in which the area surrounded by the frame VI of FIG. 4 is enlarged.

FIG. 7 is a schematic plan view showing the vicinity of the boundary between a dummy pixel area and an outer circumference area of the first embodiment in an enlarged manner.

FIG. 8 is a schematic cross-sectional view of the dummy pixel area and the outer circumference area along VIII-VIII line of FIG. 7.

FIG. 9 is a schematic plan view of a mother substrate according to the first embodiment.

FIG. 10 is a schematic plan view of a panel portion according to the first embodiment.

FIG. 11 is a flowchart showing an example of a manufacturing method according to the first embodiment.

FIG. 12A is a schematic cross-sectional view showing the manufacturing process of the display device.

FIG. 12B is a schematic cross-sectional view showing a process following FIG. 12A.

FIG. 12C is a schematic cross-sectional view showing a process following FIG. 12B.

FIG. 12D is a schematic cross-sectional view showing a process following FIG. 12C.

FIG. 12E is a schematic cross-sectional view showing a process following FIG. 12D.

FIG. 12F is a schematic cross-sectional view showing a process following FIG. 12E.

FIG. 12G is a schematic cross-sectional view showing a process following FIG. 12F.

FIG. 13 is a schematic plan view showing the configuration of a comparative example.

FIG. 14 is a schematic cross-sectional view of the dummy pixel area and the outer circumference area along the XIV-XIV line of FIG. 7.

FIG. 15 is a schematic plan view showing a configuration according to the second embodiment.

FIG. 16 is a schematic cross-sectional view of the dummy pixel area and the outer circumference area along the XVI-XVI line of FIG. 15.

FIG. 17 is a schematic plan view showing a configuration according to the third embodiment.

FIG. 18 is a schematic cross-sectional view of the dummy pixel area and the outer circumference area along the XVIII-XVIII line of FIG. 17.

FIG. 19 is a schematic plan view showing a configuration according to the fourth embodiment.

FIG. 20 is a schematic plan view showing a configuration according to the fifth embodiment.

FIG. 21 is a schematic plan view showing a configuration according to the sixth embodiment.

### DETAILED DESCRIPTION

In general, according to one embodiment, a display device includes a substrate having a display area for displaying images, a plurality of pixels provided in the display area and each including a lower electrode, an upper electrode located above the lower electrode, and an organic layer located between the lower electrode and the upper electrode and emitting light based on application of voltage, a dummy pixel area surrounding the display area and including a plurality of dummy pixels not displaying images, and a partition provided in the display area, the dummy pixel area and an outer circumference area surrounding the dummy pixel area, the partition including a lower portion having conductivity and an upper portion having an end portion protruding relative to a side surface of the lower portion. Further, the partition has a plurality of slits provided in the display area and the dummy pixel area. The slits are not provided at a boundary between the dummy pixel area and the outer circumference area.

In general, according to one embodiment, a display device includes a substrate having a display area for displaying images, a plurality of pixels provided in the display area and each including a lower electrode, an upper electrode located above the lower electrode, and an organic layer located between the lower electrode and the upper electrode and emitting light based on application of voltage, a dummy pixel area surrounding the display area and including a plurality of dummy pixels not displaying images, a partition provided in the display area, the dummy pixel area and an outer circumference area surrounding the dummy pixel area, the partition including a lower portion having conductivity and an upper portion having an end portion protruding relative to a side surface of the lower portion, a first sealing layer formed of an inorganic insulating material and covering the plurality of pixels and the plurality of dummy pixels and a second sealing layer formed of an inorganic insulating material and covering the outer circumference area. Further, the partition has a plurality of slits provided at least in the display area and the dummy pixel area. At least one of the plurality of slits is located at a boundary between the dummy pixel area and the outer circumference area. The second sealing layer covers the slit located at the boundary.

These configurations can improve the yield of the display device.

Embodiments will be described hereinafter with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z-direction. The Z-direction is the normal direction of a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

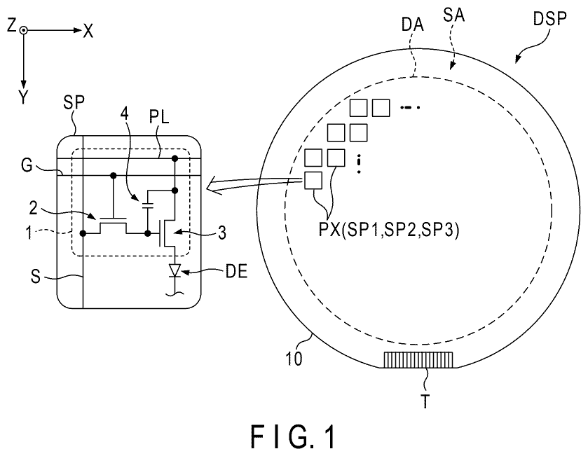

FIG. 1 is a view showing a configuration example of a display device DSP according to the first embodiment. The display device DSP comprises an insulating substrate 10. The substrate 10 has a display area DA for displaying images and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP that display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of the source electrode and the drain electrode of the pixel switch 2 is connected to the signal line S. The other is connected to the gate electrode of the drive transistor 3 and the capacitor 4. In the drive transistor 3, one of the source electrode and the drain electrode is connected to the power line PL and the capacitor 4. The other is connected to a display element DE.

The configuration of the pixel circuit 1 is not limited to the example of the figure. For example, the pixel circuit 1 may comprise more thin-film transistors and capacitors.

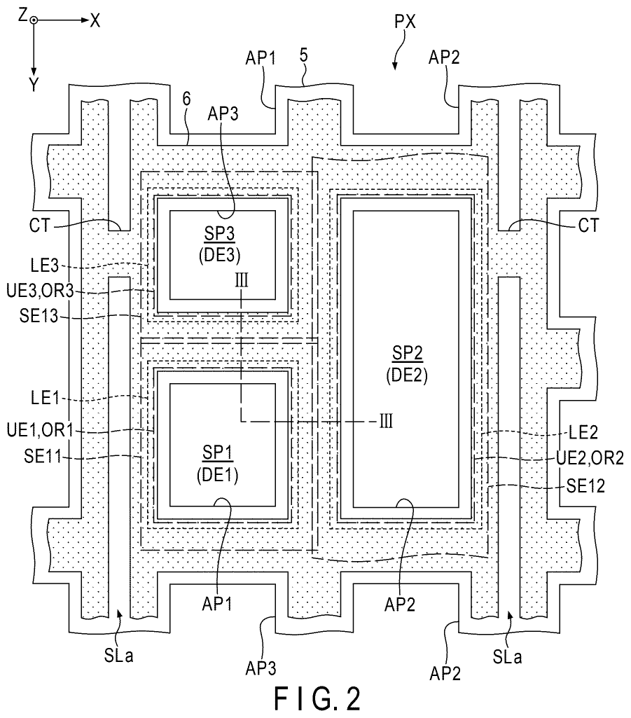

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2 and AP3 in the respective subpixels SP1, SP2 and SP3. In the example of FIG. 2, each of the pixel apertures AP1, AP2, and AP3 has a rectangular shape. The planar size of the pixel aperture AP1 is greater than that of the pixel aperture AP3. The planar size of the pixel aperture AP2 is greater than that of the pixel aperture AP1. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2. The lower electrode LE3, the upper electrode UE3, and the organic layer OR3 constitute a display element DE3 of the subpixel SP3. Each of the display elements DE1, DE2, and DE3 may further include a cap layer to be described later. The rib layer 5 surrounds each of the display elements DE1, DE2, and DE3.

A conductive partition 6 is provided above the rib layer 5. The partition 6 functions as lines which apply common voltage to the upper electrodes UE1, UE2, and UE3. The partition 6 entirely overlaps the rib layer 5 and has the same planar shape as that of the rib layer 5. The partition 6 surrounds the subpixels SP1, SP2, and SP3.

The partition 6 has a plurality of slits SLa extending in the Y-direction. In the example of FIG. 2, the subpixels SP1, SP2, and SP3 constituting one pixel PX are provided between two slits SLa in the X-direction. Further, the partition 6 has a connection portion CT, which connects portions divided by the slits SLa to one another. The layout of the slits SLa and the connection portion CT is not limited to the example of FIG. 2. For example, slits SLa that are continuous between both end portions in the Y-direction of the display area DA may be provided.

Sealing layers SE11, SE12, and SE13 (the first sealing layers) are provided in the respective subpixels SP1, SP2, and SP3. The sealing layer SE11 continuously covers the display element DE1 and the partition 6 around the display element DE1. The sealing layer SE12 continuously covers the display element DE2 and the partition 6 around the display element DE2. The sealing layer SE13 continuously covers the display element DE3 and the partition 6 around the display element DE3.

In the example of FIG. 2, the sealing layers SE11, SE12, and SE13 do not overlap the slits SLa. As another example, at least one of the sealing layers SE11, SE12, and SE13 may overlap the slit SLa.

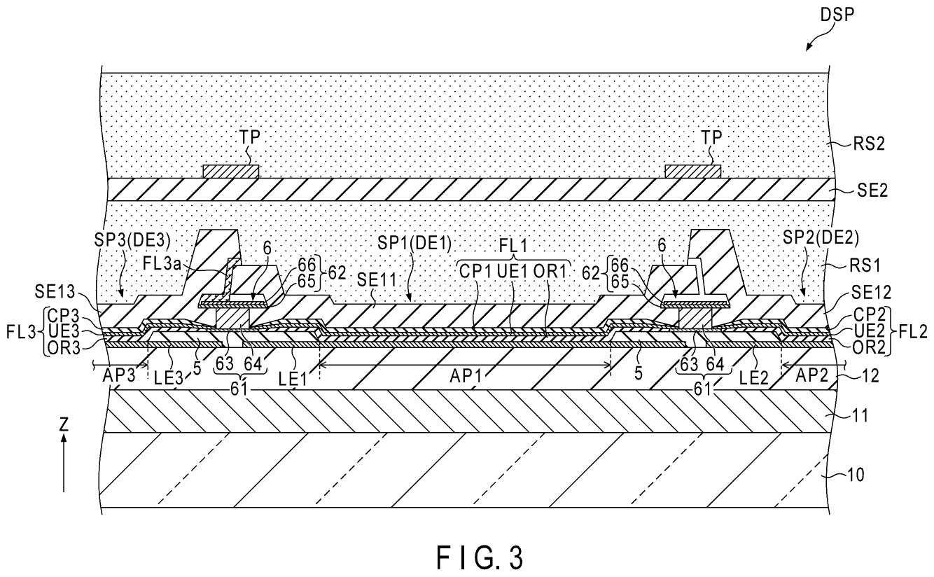

FIG. 3 is a schematic cross-sectional view of the display device DSP along the line III-III of FIG. 2. A circuit layer 11 is provided on the substrate 10 described above. The circuit layer 11 includes various circuits and lines such as the pixel circuit 1, scanning line G, signal line S, and power line PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. The periphery portions of the lower electrodes LE1, LE2, and LE3 are covered with the rib layer 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib layer 5 and an upper portion 62 provided on the lower portion 61. The upper portion 62 has the width greater than that of the lower portion 61. That is, the partition 6 has an overhang shape in which both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is thinner than the stem layer 64. In the example of FIG. 3, both end portions of the bottom layer 63 protrude relative to the side surfaces of the stem layer 64.

In the example of FIG. 3, the upper portion 62 comprises a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6.

The display element DE1 includes a cap layer CP1 covering the upper electrode UE1. The display element DE2 includes a cap layer CP2 covering the upper electrode UE2. The display element DE3 includes a cap layer CP3 covering the upper electrode UE3. The cap layers CP1, CP2, and CP3 function as optical adjustment layers, which improve the extraction efficiency of the light emitted from the organic layers OR1, OR2, and OR3, respectively.

In the following explanation, a multilayer body including the organic layer OR1, the upper electrode UE1, and the cap layer CP1 is called a stacked film FL1. A multilayer body including the organic layer OR2, the upper electrode UE2, and the cap layer CP2 is called a stacked film FL2. A multilayer body including the organic layer OR3, the upper electrode UE3, and the cap layer CP3 is called a stacked film FL3.

Sealing layers SE11, SE12 and SE13 are provided in the respective subpixels SP1, SP2 and SP3. Further, the sealing layer SE11 continuously covers the stacked film FL1 and the partition 6 around the stacked film FL1. Further, the sealing layer SE12 continuously covers the stacked film FL2 and the partition 6 around the stacked film FL2. Further, the sealing layer SE13 continuously covers the stacked film FL3 and the partition 6 around the stacked film FL3.

The sealing layers SE11, SE12, and SE13 are covered with a resin layer RS1. The resin layer RS1 is covered with the sealing layer SE2. The sealing layer SE2 is covered with a resin layer RS2. The resin layers RS1 and RS2 and the sealing layer SE2 are continuously provided in at least the entire display area DA and partly extend in the surrounding area SA as well.

In the example of FIG. 3, a touch panel electrode TP for detecting touch operations by a user is provided on the sealing layer SE2. For example, the touch panel electrode TP is formed of a metal material and has the same shape as that of the partition 6 in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

In the example of FIG. 3, the end portions of the sealing layers SE11 and SE12 overlap in the Z-direction above the partition 6 between the subpixels SP1 and SP2. Further, the end portions of the sealing layers SE11 and SE13 overlap in the Z-direction above the partition 6 between the subpixels SP1 and SP3.

For example, a gap is formed between the sealing layer SE11 and the upper portion 62 of the partition 6. Further, a gap is formed between the sealing layer SE12 and the upper portion 62, an end portion of the sealing layer SE11 and an end portion of the sealing layer SE12, and the like. These gaps result from eliminating the stacked films FL1 and FL2 in the manufacturing process. At least part of these gaps may be filled with the resin layer RS1.

In contrast, a stacked film FL3a is located between the sealing layer SE13 and the partition 6, between the end portion of sealing layers SE11 and the end portion SE13, and the like. The stacked film FL3a is formed, for example, by the stacked film FL3 changing its characteristics in the manufacturing processes. The stacked film FL3a may be eliminated in the manufacturing processes. In this case, gaps are formed between the sealing layer SE13 and the partition 6 and between the end portions of the sealing layers SE11 and SE13.

The organic insulating layer 12 is formed of an organic insulating material such as a polyimide. Each of the rib layer 5, the sealing layers SE11, SE12, SE13, and SE2 is formed of an inorganic insulating material such as a silicon nitride (SiNx), a silicon oxide (SiOx), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating materials) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), or an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 consists of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z-direction. The organic layers OR1, OR2, and OR3 each may have other structures such as a tandem structure including a plurality of light emitting layers.

Each of the cap layers CP1, CP2, and CP3 has, for example, a multilayer structure in which a plurality of transparent layers are stacked. These transparent layers could include a layer formed of an inorganic material and a layer formed of an organic material. The transparent layers have refractive indices different from one another. For example, the refractive indices of these transparent layers are different from those of the upper electrodes UE1, UE2, and UE3 and those of the sealing layers SE11, SE12, and SE13. At least one of the cap layers CP1, CP2, and CP3 may be omitted.

For example, each of the bottom layer 63 and the stem layer 64 of the partition 6 is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be formed of an insulating material.

The first top layer 65 of the partition 6 is formed of, for example, a metal material. The second top layer 66 of the partition 6 is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, ITO or IZO can be used. The upper portion 62 may comprise three or more layers or may consist of a single layer. The upper portion 62 may further include a layer formed of an insulating material.

Common voltage is applied to the partition 6. This common voltage is applied to each of the upper electrodes UE1, UE2, and UE3, which contact the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light beams of the green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light beams of the same color (for example, white). In this case, the display device DSP may comprise a color filter that converts the light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

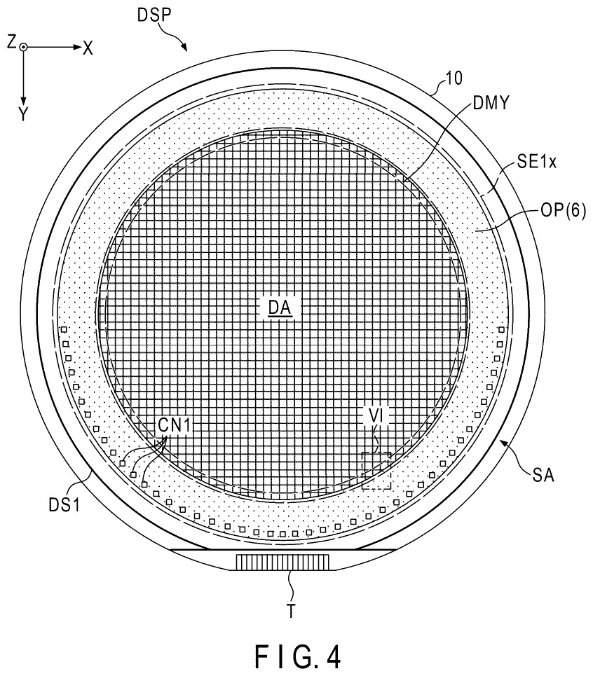

FIG. 4 is a schematic plan view of the display device DSP. In the example of this figure, a dummy pixel area DMY surrounding the display area DA is provided in the surrounding area SA. The partition 6 is provided in the dummy pixel area DMY as well. Further, the partition 6 is provided in the outer circumference area OP surrounding the dummy pixel area DMY. The partition 6 is covered with a sealing layer SE1x (the second sealing layer) in the outer circumference area OP. The sealing layer SE1x is formed of the same inorganic insulating material as those of the sealing layers SE11, SE12, and SE13.

A dam structure DS1 is provided outside the sealing layer SE1x. The terminal portion T is located outside the dam structure DS1. For example, each of the dummy pixel area DMY, the outer circumference area OP, the sealing layer SE1x, and the dam structure DS1 has a circular shape concentric with the display area DA.

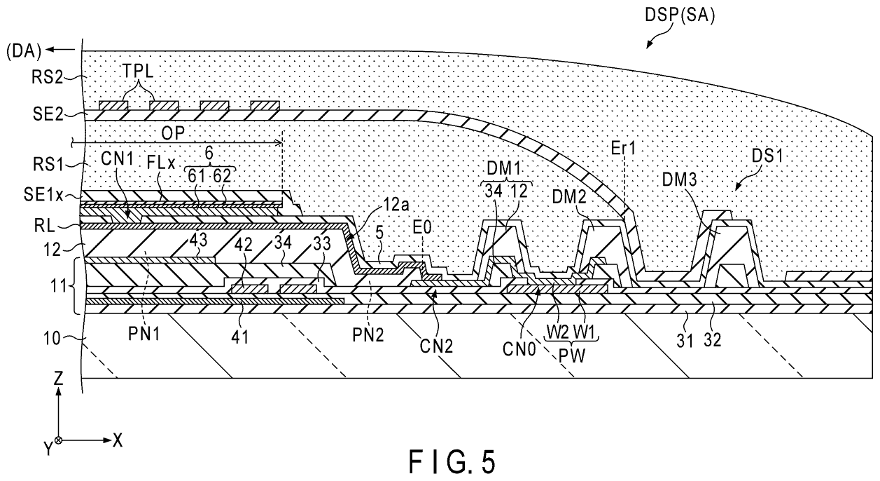

In the outer circumference area OP, the partition 6 is connected to a relay layer RL and the power supply line PW that are provided on the lower layer via a plurality of contact portions CN1 (refer to FIG. 5). The power supply line PW is connected to the terminal portion T and receives common voltage from the terminal portion T. This common voltage of the partition 6 is applied to each of the upper electrodes UE1, UE2, and UE3 contacting the partition 6. In the example of FIG. 4, the plurality of contact portions CN1 are arcuately provided in the terminal portion T side.

FIG. 5 is a schematic cross-sectional view of the surrounding area SA of the display device DSP. The configuration of the partition 6 in the outer circumference area OP has the same configuration as that of the partition 6 in the display area DA shown in FIG. 3.

The circuit layer 11 shown in FIG. 3 has inorganic insulating layers 31, 32, and 33 formed of an inorganic insulating material, an organic insulating layer 34 formed of an organic insulating material, and metal layers 41, 42, and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

For example, the dam structure DS1 comprises a dam portion DM1, a dam portion DM2 surrounding the dam portion DM1, and a dam portion DM3 surrounding the dam portion DM2. For example, each of the dam portions DM1, DM2, and DM3 has a circular shape surrounding the display area DA. The number of the dam portions that the dam structure DS1 comprises is not limited to three.

Each of the dam portions DM1, DM2, and DM3 protrudes toward the upper side of the substrate 10. In the example of FIG. 5, the dam portion DM1 consists of the organic insulating layers 12 and 34. Similarly, the dam portions DM2 and DM3 consist of the organic insulating layers 12 and 34. In other words, in the present embodiment, the dam portions DM1, DM2, and DM3 are formed of the same materials as the organic insulating layers 12 and 34 in the same layers as the organic insulating layers 12 and 34.

The power line PW to which common voltage is applied is provided below the dam portions DM1 and DM2. The power line PW has a first line W1 formed of the metal layer 42 and a second line W2 formed of the metal layer 43.

In the example of FIG. 5, the first line W1 and the second line W2 contact each other in a contact portion CN0 located between the dam portions DM1 and DM2. Part of the second line W2 is located between the organic insulating layers 12 and 34 in each of the dam portions DM1 and DM2.

In the surrounding area SA, the conductive relay layer RL, which connects the partition 6 and the power supply line PW to each other, and the rib layer 5 are provided. For example, the relay layer RL is formed of the same material and process as those of the lower electrodes LE1, LE2, and LE3 described above.

The relay layer RL is located on the display area DA side (the left side in the figure) relative to the dam portion DM1 and covers the organic insulating layer 12. The rib layer 5 continuously covers the relay layer RL and the dam portions DM1, DM2, and DM3.

In the outer circumference area OP, the partition 6 is provided on the rib layer 5. The partition 6 contacts the relay layer RL in the contact portion CN1 shown also in FIG. 4. More specifically, the rib layer 5 is open in the contact portion CN1. The lower portion 61 of the partition 6 (specifically, the bottom layer 63) contacts the relay layer RL through this aperture. The contact portion CN1 is provided above the organic insulating layer 12.

The relay layer RL contacts the second line W2 of the power supply line PW in a contact portion CN2. The contact portion CN2 is located between an end portion E0 of the organic insulating layer 12 and the dam portion DM1 in plan view.

In the outer circumference area OP, a stacked film FLx is provided on the partition 6. The partition 6 and the stacked film FLx are covered with the sealing layer SE1x. The stacked film FLx is formed by the same process and material as those of any of the stacked films FL1, FL2, and FL3 shown in FIG. 3. The sealing layer SE1x is formed by the same process and material as those of any of the sealing layers SE11, SE12, and SE13 shown in FIG. 3. The present embodiment assumes cases where the stacked film FLx and the sealing layer SE1x are respectively formed as the same process and material as those of the respective stacked film FL3 and the sealing layer SE13. That is, the stacked film FLx has the upper electrode UE3, the organic layer OR3, and the cap layer CP3.

The resin layer RS1, the sealing layer SE2, and the resin layer RS2 shown in FIG. 3 are provided above the sealing layer SE1x. Further, a touch panel line TPL connected to the touch panel electrode TP shown in FIG. 3 is provided on the sealing layer SE2. For example, the touch panel line TPL is formed of the same material as that of the touch panel electrode TP.

The resin layer RS1 covers the sealing layer SE1x and the rib layer 5. In the manufacturing of the display device DSP, the dam portions DM1, DM2, and DM3 function to dam up the resin layer RS1 that before being cured. In the example of FIG. 5, an end portion Er1 of the resin layer RS1 is located above the dam portion DM2. That is, the resin layer RS1 partly covers the dam portions DM1 and DM2. The position of the end portion Er1 is not limited to this example.

The sealing layer SE2 covers the end portion Er1 of the resin layer RS1. The sealing layer SE2 contacts the rib layer 5 in an area located further outward than the end portion Er1 (the right side in the figure). In the example of FIG. 5, the sealing layer SE2 is removed in the vicinity of the dam portion DM3. The resin layer RS1 is surrounded by the sealing layer SE1x, the rib layer 5, and the sealing layer SE2. This configuration prevents the moisture intrusion into the resin layer RS1.

The organic insulating layer 12 may have a first portion PN1 and a second portion PN2 thinner than the first portion PN1 as shown in FIG. 5. The second portion PN2 is formed in the periphery of the first portion PN1. That is, the second portion PN2 covers the first portion PN1 in plan view. Each of the partition 6, the stacked film FLx, and the sealing layer SE1x in the outer circumference area OP is located above the first portion PN1.

In the example of FIG. 5, the organic insulating layer 34 is provided below the first portion PN1 but not provided below the second portion PN2. A step portion 12a is formed on the organic insulating layer 12 in the vicinity of the end portion of the organic insulating layer 34. For example, of the organic insulating layer 12, the portion that is closer to the dam portion DM1 relative to the step portion 12a corresponds to the second portion PN2.

The relay layer RL covers the first portion PN1, the second portion PN2, and the step portion 12a. If the organic insulating layer 12 does not have the second portion PN2, the step portion 12a becomes steeper. If the relay layer RL is formed to cover this steep step portion 12a, the relay layer RL may be deformed. To the contrary, providing the second portion PN2 can decrease the influence of the step portion 12a, and thus the relay layer RL can be sufficiently formed.

The sectional structure shown in FIG. 5 can be applied to any position of the surrounding area SA except the vicinity of the terminal portion T. The configuration of the surrounding area SA is not necessarily limited to the one shown in FIG. 5. For example, the organic insulating layer 12 may not have the second portion PN2. The structure for connecting the partition 6 and the power supply line PW together can be changed according to the position of the power supply line PW, the layer configuration of the circuit layer 11, and the like.

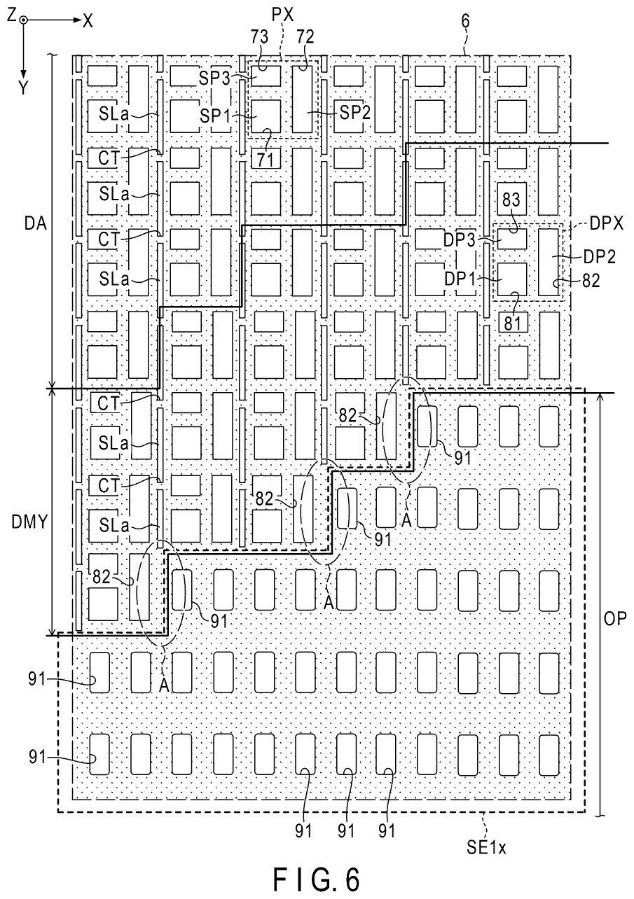

FIG. 6 is a schematic plan view in which the area surrounded by the frame VI of FIG. 4 is enlarged. A plurality of dummy pixels DPX are provided in the dummy pixel area DMY. For example, each dummy pixel DPX includes dummy subpixels DP1, DP2, and DP3. Each of the dummy subpixels DP1, DP2, and DP3 has the configuration similar to those of the respective subpixels SP1, SP2, and SP3 shown in FIG. 2.

That is, the dummy subpixel DP1 comprises the lower electrode LE1, the organic layer OR1, the upper electrode UE1, and the sealing layer SE11. The dummy subpixel DP2 comprises the lower electrode LE2, the organic layer OR2, the upper electrode UE2, and the sealing layer SE12. The dummy subpixel DP3 comprises the lower electrode LE3, the organic layer OR3, the upper electrode UE3, and the sealing layer SE13.

However, the dummy subpixels DP1, DP2, and DP3 are configured not to emit light. This configuration may be realized by, for example, disconnecting part of the pixel circuit 1 in each of the dummy subpixels DP1, DP2, and DP3. The pixel apertures AP1, AP2, and AP3 may be omitted in the respective dummy subpixels DP1, DP2, and DP3. Thus, the rib layer 5 is interposed between the organic layers OR1, OR2, and OR3 and the lower electrodes LE1, LE2, and LE3. Thus, a voltage for making the organic layers OR1, OR2, and OR3 to emit light is not supplied to these organic layers OR.

Part of the partition 6 is located in the dummy pixel area DMY and surrounds each of the plurality of dummy pixels DPX. More specifically, the partition 6 surrounds each of dummy subpixels DP1, DP2 and DP3.

The outer circumference area OP is formed continuously with the partition 6 in the dummy pixel area DMY. For example, the outer circumference area OP corresponds to the portion overlapping the sealing layer SE1x in the partition 6. The lower electrodes LE1, LE2, and LE3 and a pixel circuit PC are provided in the display area DA and the dummy pixel area DMY but are not provided in outer circumference area OP.

For example, the partitions 6 in the display area DA and the dummy pixel area DMY have the same aperture pattern. That is, the partition 6 has apertures 71, 72, and 73 (the first apertures) in the respective subpixels SP1, SP2, and SP3 and has apertures 81, 82, and 83 (the second apertures) in the dummy subpixels DP1, DP2, and DP3. The apertures 71, 72, and 73 have the same shape as those of the respective apertures 81, 82, and 83. The arrangement of the apertures 71, 72, and 73 is the same as the apertures 81, 82, and 83.

The partition 6 has a plurality of apertures 91 (the third apertures) provided in the outer circumference area OP. These apertures 91 are arranged at regular intervals in the X-direction and the Y-direction. For example, each aperture 91 has a rectangular shape elongated in the Y-direction but may have a different shape.

The slit SLa and the connection portion CT are provided in the display area DA. The slit SLa and the connection portion CT are provided in the dummy pixel area DMY as well. In contrast, the slit SLa and the connection portion CT are not provided in the outer circumference area OP in the present embodiment.

In the present embodiment, the outer shape of each of the display area DA, the dummy pixel area DMY, and the outer circumference area OP is a circular shape. This outer shape can be achieved by forming each of the boundary between the display area DA and the dummy pixel area DMY and the boundary between the dummy pixel area DMY and outer circumference area OP in a stepped shape as shown in FIG. 6.

This boundary between the dummy pixel area DMY and the outer circumference area OP that have the stepped shape forms the area in which the aperture 82 in the dummy pixel area DMY and the apertures 91 in the outer circumference area OP are arranged in the X-direction as the portion surrounded by the frame A indicates. In the present embodiment, the slit SLa is not provided in such area, in other words, the area between the apertures 82 and 91 arranged in the X-direction.

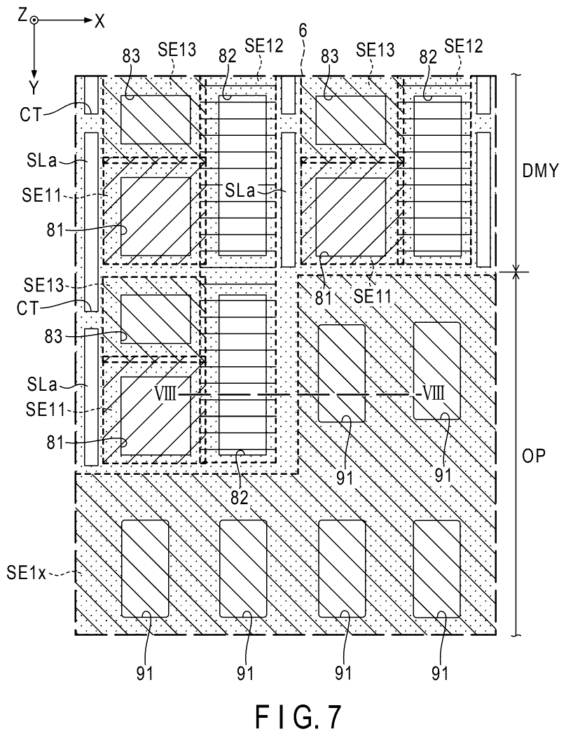

FIG. 7 is a schematic plan view showing the vicinity of the boundary between the dummy pixel area DMY and the outer circumference area OP in an enlarged manner. In the same manner as the subpixels SP1, SP2, and SP3, the respective sealing layers SE11, SE12, and SE13 are provided in the dummy subpixels DP1, DP2, and DP3. The sealing layer SE13 is continuous across the plurality of apertures 82 arranged in the Y-direction.

In the example of FIG. 7, the sealing layers SE11, SE12, and SE13 do not overlap the slits SLa. As another example, at least one of the sealing layers SE11, SE12, and SE13 may overlap the slit SLa.

Each aperture 91 in the outer circumference area OP overlaps the sealing layer SE1x. At the boundary between the dummy pixel area DMY and the outer circumference area OP, the sealing layer SE1x is spaced apart from each of the sealing layers SE11, SE12, and SE13. However, at this boundary, the sealing layer SE1x may overlap at least one of the sealing layers SE11, SE12, and SE13.

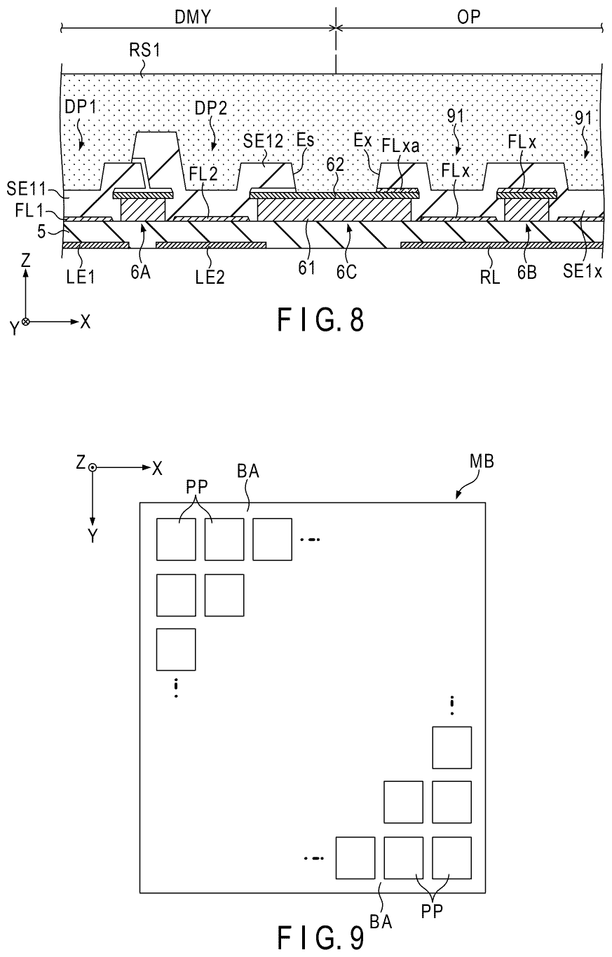

FIG. 8 is a schematic cross-sectional view of the dummy pixel area DMY and the outer circumference area OP along the VIII-VIII line of FIG. 7. This figure omits the illustration of the substrate 10, the circuit layer 11, the organic insulating layer 12, the sealing layer SE2, and the resin layer RS2. In the following descriptions, the partition 6 provided in the dummy pixel area DMY is referred to as a partition 6A, the partition 6 provided in the outer circumference area OP is referred to as a partition 6B, and the partition 6 provided at the boundary between the dummy pixel area DMY and the outer circumference area OP is referred to as a partition 6C.

In the dummy subpixel DP1, the lower electrode LE1, the stacked film FL1, and the sealing layer SE11 are provided. In the dummy subpixel DP2, the lower electrode LE2, the stacked film FL2, and the sealing layer SE12 are provided. In the example of FIG. 8, no pixel apertures are provided in the rib layer 5 in the dummy subpixels DP1 and DP2. Thus, the lower electrode LE1 faces the stacked film FL1 via the rib layer 5. Thus, the lower electrode LE2 faces the stacked film FL2 via the rib layer 5.

The sealing layer SE11 continuously covers the stacked film FL1 and the partition 6A around the stacked film FL1. The sealing layer SE12 continuously covers the stacked film FL2 and the partitions 6A and 6C around the stacked film FL2. In the example of FIG. 8, the end portions of the sealing layers SE11 and SE12 overlap in the Z-direction above the partition 6A. For example, a gap is formed between the sealing layer SE11 and the upper portion 62 of the partition 6A. Further, a gap is formed between the sealing layer SE12 and the upper portions 62 of the partitions 6A and 6C and between the end portion of the sealing layer SE11 and the end portion of the sealing layer SE12, and the like. At least part of these gaps may be filled with the resin layer RS1.

In the outer circumference area OP, the stacked film FLx is provided above the upper portion 62 of the partition 6B and in the apertures 91. The sealing layer SE1x continuously covers part of these stacked film FLx, the partition 6B, and the partition 6C.

A stacked film FLxa is provided between the sealing layer SE1x and the upper portion 62 of the partition 6C. The stacked film FLxa is formed, for example by the stacked film FLx changing its characteristics in the manufacturing processes. The stacked film FLxa may be eliminated in the manufacturing processes. In that case, a gap is formed between the sealing layer SE1x and the partition 6C.

In the present embodiment, an end portion Es of the sealing layer SE12 and an end portion Ex of the sealing layer SE1x are spaced apart from each other on the partition 6C. The resin layer RS1 covers the sealing layers SE11, SE12, and SE1x. Further, in the area between the end portions Es and Ex, the resin layer RS1 covers the upper portion 62 of the partition 6C exposed from the sealing layers SE12 and SE1x.

The following describes an example of the manufacturing method of the display device DSP. In the manufacturing of the display device DSP, a large mother substrate is fabricated, the mother substrate comprising a plurality of areas (panel portions) each including a portion corresponding to the display device DSP.

FIG. 9 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel portions PP provided in a matrix and a margin area BA around these panel portions PP. In the example of FIG. 9, the panel portions PP are arranged in the X-direction and the Y-direction via the margin area BA. The layout of the panel portions PP in the mother substrate MB is not limited to this example. As another example, some of the panel portions PP may be arranged without interposing the margin area BA therebetween.

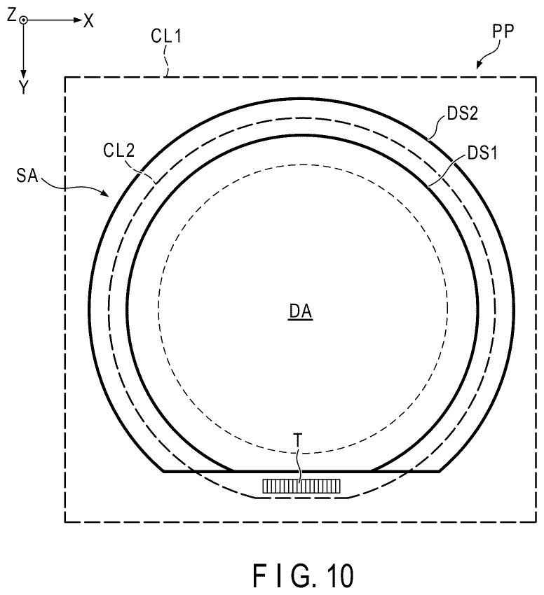

FIG. 10 is a schematic plan view of the panel portion PP. The outer shape of the panel portion PP corresponds to a cut line CL1 for cutting out each panel portion PP from the mother substrate MB.

Each panel portion PP has the display area DA and the surrounding area SA. The surrounding area SA in the panel portion PP corresponds to the area between the display area DA and the cut line CL1.

The surrounding area SA further has a cut line CL2, which is the outer shape of the substrate 10 of the display device DSP. In the manufacturing of the display device DSP, the panel portion PP is cut out from the mother substrate MB along the cut line CL1. Further, the display device DSP is cut out from the panel portion PP along the cut line CL2.

In addition to the dam structure DS1, the panel portion PP comprises a dam structure DS2. The dam structure DS2 functions to dam up the resin layer RS2 before being cured. For example, the dam structure DS2 has a plurality of dam portions formed of the organic insulating layers 12 and 34 in the same manner as the dam portions DM1, DM2, and DM3.

The dam structure DS1 is located between the cut line CL2 and the display area DA and surrounds the display area DA. The dam structure DS2 is located between the cut lines CL1 and CL2 and surrounds the cut line CL2. In the example of FIG. 10, the dam structures DS1 and DS2 merge in the vicinity of the terminal portion T. This merged portion passes between the terminal portion T and the display area DA.

The most part of the cut line CL2 is located between the dam structures DS1 and DS2. In the example of FIG. 10, the cut line CL2 is located on the outside of the dam structures DS1 and DS2 in the vicinity of the terminal portion T. That is, the cut line CL2 traverses the dam structure DS2 in the vicinity of the terminal portion T.

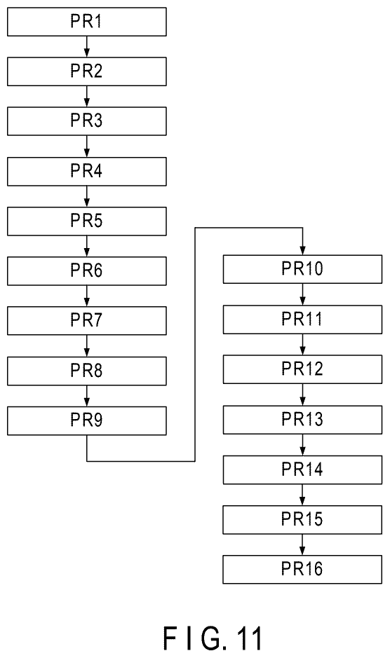

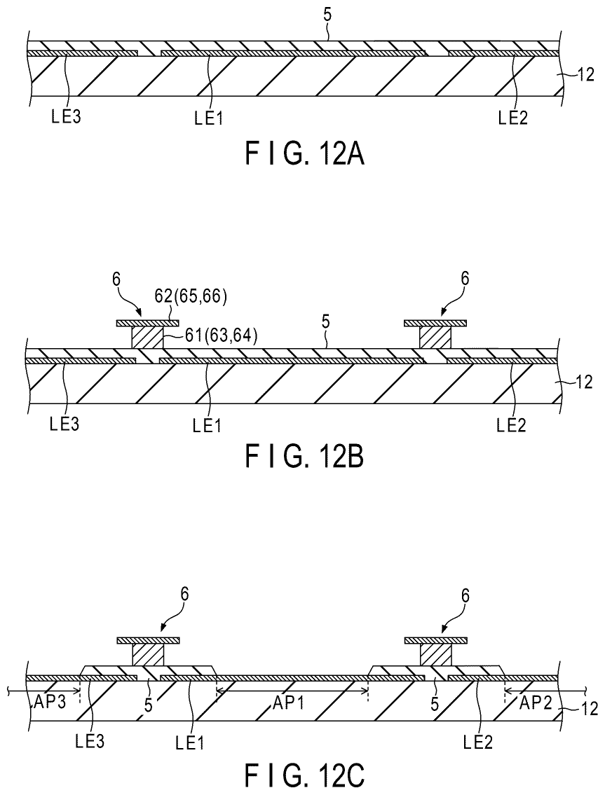

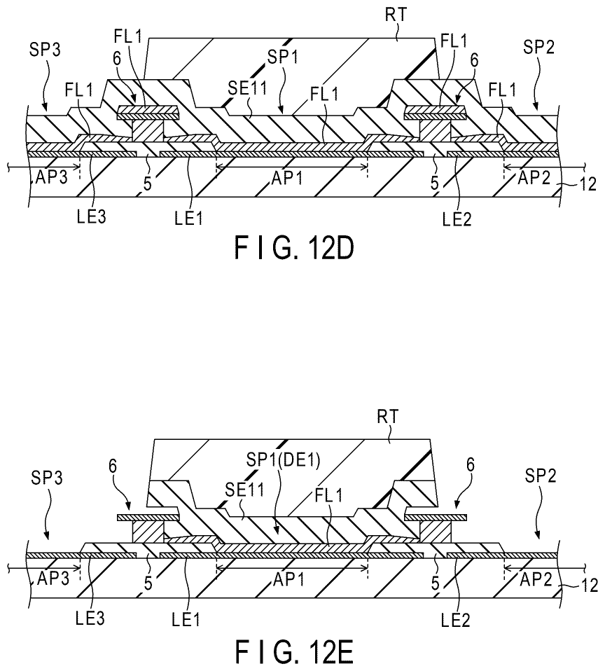

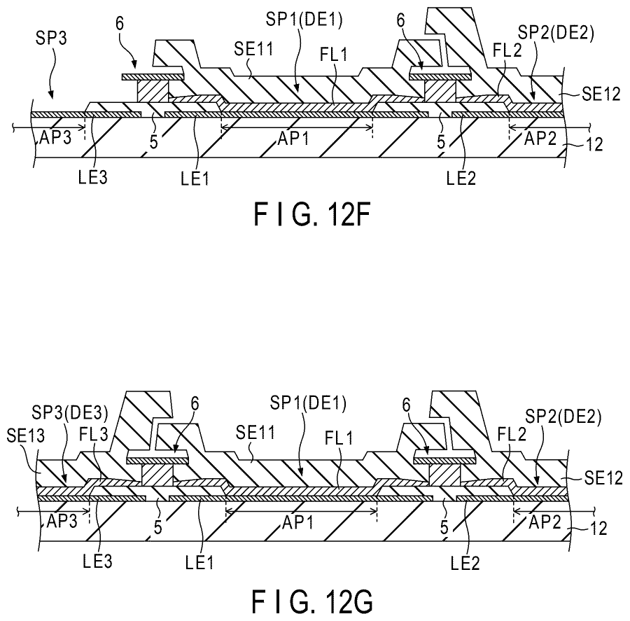

FIG. 11 is a flowchart showing an example of the manufacturing method of the display device DSP. FIG. 12A to FIG. 12G are schematic cross-sectional views showing the manufacturing process of the display device DSP. FIG. 12A to FIG. 12G mainly focus on the display area DA and omit the elements below the organic insulating layer 12.

In the formation of the panel portions PP, first, the circuit layer 11 including the inorganic insulating layers 31, 32, and 33, the organic insulating layer 34, the metal layers 41, 42, and 43, and the like is formed on the substrate 10 of the mother substrate MB (the process PR1 in FIG. 11). Further, the organic insulating layer 12 covering the circuit layer 11 is formed (the process PR2 in FIG. 11). At this time, the dam structures DS1 and DS2 are formed as well.

After the process PR2, the lower electrodes LE1, LE2, and LE3 are formed on the organic insulating layer 12 as shown in FIG. 12A (the process PR3 in FIG. 11). Further, the rib layer 5 covering the lower electrodes LE1, LE2, and LE3 is formed in the entire mother substrate MB as shown in FIG. 12A (the process PR4 in FIG. 11). At this time, the pixel apertures AP1, AP2, and AP3 are not provided in the rib layer 5. The rib layer 5 can be formed by chemical vapor deposition (CVD).

After the formation of the rib layer 5, the partition 6 is formed on the rib layer 5 as shown in FIG. 12B (the process PR5 in FIG. 11). For example, in the formation of the partition 6, material layers of the bottom layer 63, the stem layer 64, the first top layer 65, and the second top layer 66 are formed over the entire mother substrate MB. Further, a resist having the shape corresponding to the partition 6 is provided on these layers. The etching each layer using this resist as a mask can form the partition 6.

Next, the pixel apertures AP1, AP2, and AP3 are formed in the rib layer 5 as shown in FIG. 12C (the process PR6 in FIG. 11). The pixel apertures AP1, AP2, and AP3 may be formed prior to the formation of the partition 6.

After the process PR6, a process for forming the display element DE1 is performed (the process PR7 in FIG. 11). In the formation of the display element DE1, the stacked film FL1 and the sealing layer SE11 are formed first as shown in FIG. 12D. As shown in FIG. 3, the stacked film FL1 includes, the organic layer OR1, which contacts the lower electrode LE1 through the pixel aperture AP1, the upper electrode UE1, which covers the organic layer OR1, and the cap layer CP1, which covers the upper electrode UE1. For example, the organic layer OR1, the upper electrode UE1, and the cap layer CP1 may be formed by vapor deposition. The sealing layer SE11 can be formed, for example, by CVD.

The stacked film FL1 and the sealing layer SE11 are formed in the entire mother substrate MB including the surrounding area SA and the margin area BA as well as the display area DA of each panel portion PP. The stacked film FL1 is divided by the partition 6 having an overhang shape. The sealing layer SE11 continuously covers these portions, into which the stacked film FL1 has been divided, and the partition 6.

Subsequently, the stacked film FL1 and the sealing layer SE11 are patterned. In this patterning, a resist RT is provided on the sealing layer SE11 as shown in FIG. 12D. The resist RT covers the subpixel SP1 and part of the partition 6 around the subpixel SP1.

Subsequently, an etching process using the resist RT as a mask is performed. This process removes the portions that are exposed from the resist RT of the stacked film FL1 and the sealing layer SE11 as shown in FIG. 12E. In other words, the portions that overlap the lower electrode LE1 of the stacked film FL1 and the sealing layer SE11 remain, and the other portions are removed. This process forms the display element DE1 in the subpixel SP1. For example, this etching process removes the stacked film FL1 and the sealing layer SE11 in the surrounding area SA and the margin area BA. This etching process may include wet etching and dry etching performed in order for the sealing layer SE11, the cap layer CP1, the upper electrode UE1, and the organic layer OR1. After these etching processes, the resist RT is removed (stripped).

After the process PR7, a process for forming the display element DE2 is performed (the process PR8 in FIG. 11). The display element DE2 can be formed by the same procedure as that of the display element DE1. That is, in the formation of the display element DE2, the stacked film FL2 and the sealing layer SE12 are formed in the entire mother substrate MB. The stacked film FL2 includes the organic layer OR2, which contacts the lower electrode LE2 through the pixel aperture AP2, the upper electrode UE2, which covers the organic layer OR2, and the cap layer CP2, which covers the upper electrode UE2 as shown in FIG. 3.

The organic layer OR2, the upper electrode UE2, and the cap layer CP2 may be formed by, for example, vapor deposition. The sealing layer SE12 can be formed, for example, by CVD. Patterning these stacked film FL2 and sealing layer SE2 forms the display element DE2 in the subpixel SP2 as shown in FIG. 12F. For example, the etching in this patterning removes the stacked film FL2 and the sealing layer SE12 in the surrounding area SA and the margin area BA.

After the process PR8, a process for forming the display element DE3 is performed (the process PR9 in FIG. 11). The display element DE3 can be formed by the same procedures as those of the display elements DE1 and DE2. Specifically, in the formation of the display element DE3, the stacked film FL3 and the sealing layer SE13 are formed in the entire mother substrate MB. The stacked film FL3 includes, the organic layer OR3, which contacts the lower electrode LE3 through the pixel aperture AP3, the upper electrode UE3, which covers the organic layer OR3, and the cap layer CP3, which covers the upper electrode UE3 as shown in FIG. 3.

The organic layer OR3, the upper electrode UE3, and the cap layer CP3 may be formed by, for example, vapor deposition. For example, the sealing layer SE13 can be, for example, formed by CVD. Patterning these stacked film FL3 and sealing layer SE13 forms the display element DE3 in the subpixel SP3 as shown in FIG. 12G. In FIG. 12G, a gap is formed under the sealing layer SE13 on the partition 6 between the subpixels SP1 and SP3. The stacked film FL3a shown in FIG. 3 may remain in this gap.

For example, the etching in this patterning removes the stacked film FL3 and the sealing layer SE13 in the most of the surrounding area SA and margin area BA. However, the portions covering the outer circumference area OP of the stacked film FL3 and the sealing layer SE13 remain. In this manner, the remaining portions correspond to the stacked film FLx and the sealing layer SE1x.

Here, the above description assumes that the display elements DE1, DE2, and DE3 are formed in this order. However, the display elements DE1, DE2, and DE3 may be formed in another order.

After the process PR9, the resin layer RS1 is formed (the process PR10 in FIG. 11). The resin layer RS1 may be formed inside the dam structure DS1 by, for example, the ink-jet method. After the process PR10, the sealing layer SE2 is formed, for example, by CVD (the process PR11 in FIG. 11).

After the process PR11, etching for removing the rib layer 5 and the sealing layer SE2 covering the terminal portion T is performed (the process PR12 in FIG. 11). The etching is, for example, dry etching.

After the process PR12, the touch panel electrode TP and the touch panel line TPL are formed on the sealing layer SE2 (the process PR13 in FIG. 11). Further, the resin layer RS2 is formed (the process PR14 in FIG. 11). The resin layer RS2 may be formed inside the dam structure DS2 by, for example, the ink-jet method. The dam structure DS2 functions to dam up the resin layer RS2 before being cured.

After the process PR14, the mother substrate MB is cut out along the cut line CL1 (the process PR15 in FIG. 11). Further, the panel portion PP is cut out along the cut line CL2 (the process PR16 in FIG. 11). This completes the display device DSP. For example, laser cutting with infrared irradiation along the cut lines CL1 and CL2 may be adopted for cutting in the processes PR15 and PR16. The cutting in the processes PR15 and PR16 may be performed by other methods such as scribe cutting.

The embodiment described above can improve the yield of the display device DSP. The stacked films FL1, FL2, and FL3 formed by vapor deposition may have poor adherence to the base. Thus, the stacked films FL1, FL2, and FL3 and the sealing layers SE11, SE12, and SE13 covering these stacked films may be stripped from the base in the manufacturing of the display device DSP.

This stripping tends to occur in cases where the stacked films FL1, FL2, and FL3 are continuously formed in a wide range. In the display area DA, the stacked films FL1, FL2, and FL3 are divided into pieces by the partition 6. Thus, the removal described above is prevented.

In the present embodiment, the partition 6 having the plurality of apertures 91 are provided in the outer circumference area OP as well. This configuration divides the stacked films FL1, FL2, and FL3 into pieces and suppresses the stripping in the outer circumference area OP as well.

Further, the configuration of the display device DSP according to the present embodiment can achieve, for example, effects described below.

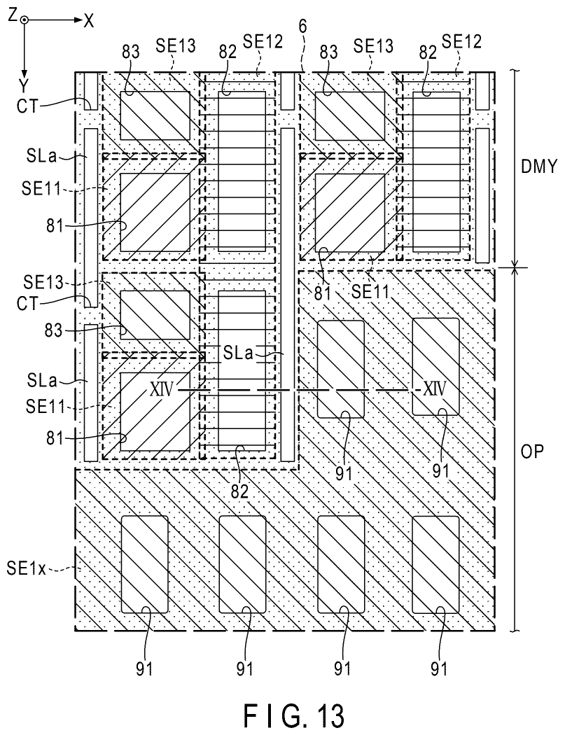

FIG. 13 is a schematic plan view of a configuration of a comparative example for the present embodiment. This figure focuses on the vicinity of the boundary between the dummy pixel area DMY and the outer circumference area OP in the same manner as FIG. 7.

In the comparative example, the slit SLa is provided in the boundary between the dummy pixel area DMY and the outer circumference area OP as well. This forms the area where the slit SLa is located between the apertures 82 and 91 arranged in the X-direction.

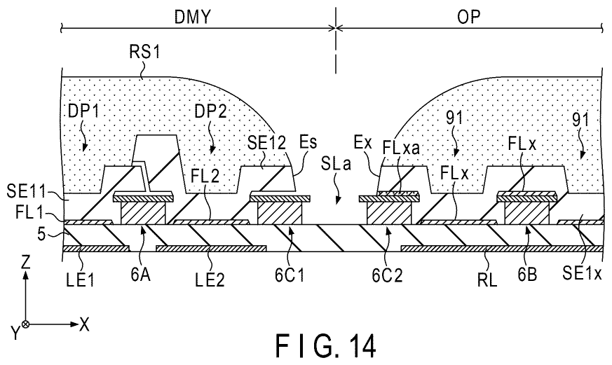

FIG. 14 is a schematic cross-sectional view of the dummy pixel area DMY and the outer circumference area OP along the XIV-XIV line of FIG. 7. In the comparative example, the portion corresponding to the partition 6C in FIG. 7 is divided into partitions 6C1 and 6C2 by the slit SLa. Further, the end portion Es of the sealing layer SE12 is located on the partition 6C1, and the end portion Ex of the sealing layer SE1x is located on the partition 6C2.

In cases where the resin layer RS1 is formed by the ink-jet method, droplets of resin materials are discharged to the display area DA, the dummy pixel area DMY, and the outer circumference area OP. Generally, these droplets spread on the sealing layers SE11, SE12, SE13, and SE1x and covers the entire portions inside the dam structure DS1.

However, the aperture pattern of the partition 6 differs between the dummy pixel area DMY and the outer circumference area OP. Thus, shapes differ between the irregularities formed on the upper surfaces of the sealing layers SE11, SE12, and SE13 in the dummy pixel area DMY and the irregularities formed on the upper surface of the sealing layer SE1x in the outer circumference area OP. When the shape of the base of the resin layer RS1 is different in this manner, the spread of the droplets in the vicinity of the boundary between the dummy pixel area DMY and the outer circumference area OP may be affected.

Further, in the comparative example shown in FIG. 14, steep steps formed by the partition 6C1 and the end portion Es of the sealing layer SE12 and steep steps formed by the partition 602 and the end portion Ex of the sealing layer SE1x are formed on both sides of the slit SLa. When such steps are formed in the boundary between the dummy pixel area DMY and the outer circumference area OP where the spreading of the droplets changes, the droplets may not spread beyond the slit SLa. In this case, coating defects where the resin layer RS1 is partially missing occurs in the vicinity of the slit SLa as shown in FIG. 14.

The coating defects may cause deformation or break in the touch panel line TPL formed above the resin layer RS1. Irregularities in the appearance of the display device DSP and moisture intrusion path may occur due to the coating defects.

In contrast, in the present embodiment, the slit SLa is not provided in the boundary between the dummy pixel area DMY and the outer circumference area OP. Thus, the steep steps such as those shown in the comparative example are not formed. Thus, the droplets of the liquid resin layer RS1 at the time of coating easily spread beyond the boundary. This suppresses the occurrence of coating defects.

Suppressing the occurrence of the coating defects can suppress the coating failure of liquid resins such as various resists applied after the formation of the resin layer RS1 as well. Such liquid resins include, for example, a resist for processing the rib layer 5 and the sealing layer SE2 in the process PR12, and a resist for processing the touch panel electrode TP and the touch panel line TPL in the process PR13.

The display device DSP may comprise a plurality of color filters corresponding to the colors of the subpixels SP1, SP2, and SP3, and a black matrix located at the boundaries between the subpixels SP1, SP2, and SP3. For example, these color filters and black matrix may be provided above the sealing layer SE2. Suppressing the occurrence of coating defects in the resin layer RS1 can suppress coating defects in the resins that are the material of these color filters and black matrix.

### Second Embodiment

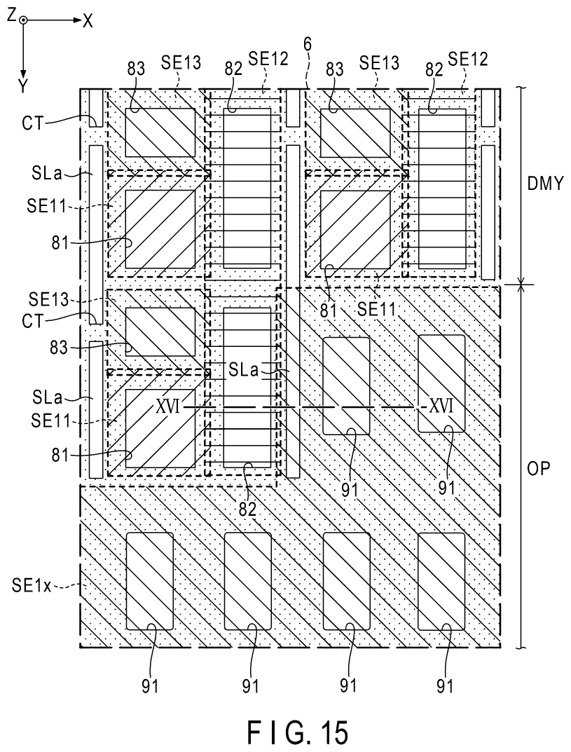

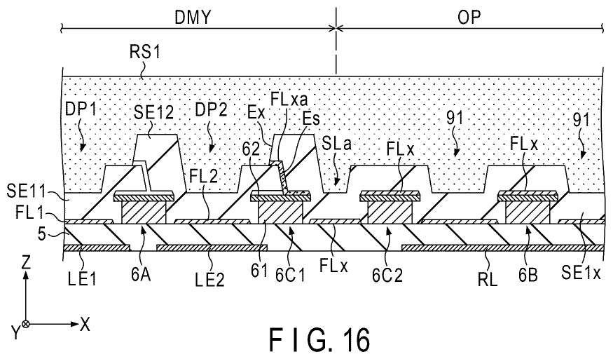

FIG. 15 is a schematic plan view showing a configuration according to the second embodiment. FIG. 16 is a schematic cross-sectional view of the dummy pixel area DMY and the outer circumference area OP along the XVI-XVI line of FIG. 15. These figures focus on the vicinity of the boundary between the dummy pixel area DMY and the outer circumference area OP in the same manner as FIG. 7 and FIG. 8.

In the present embodiment, the slit SLa is provided in the boundary between the dummy pixel area DMY and the outer circumference area OP in the same manner as the comparative example. This forms the area where the slit SLa extends in the Y-direction with passing between the apertures 82 and 91 arranged in the X-direction. However, this slit SLa is covered with the sealing layer SE1x in the present embodiment.

The partitions 6C1 and 6C2 divided by the slit SLa are provided in the vicinity of the boundary between the dummy pixel area DMY and the outer circumference area OP as shown in FIG. 16. The stacked film FLx is provided in the slit SLa. The sealing layer SE1x fills the slit SLa.

The end portion Ex of the sealing layer SE1x is located above the partition 6C1. The end portion Ex overlaps the end portion Es of the sealing layer SE12 in the Z-direction in the example of FIG. 16. The stacked film FLxa is provided between the sealing layer SE1x and the upper portion 62 of the partition 6C1. As another example, a gap is formed between the sealing layer SE1x and the upper portion 62 of the partition 6C1. At least part of these gaps may be filled with the resin layer RS1.

The configuration shown in FIG. 15 and FIG. 16 can be applied to each position where the apertures 82 and 91 are arranged in the X-direction at the boundary between the dummy pixel area DMY and the outer circumference area OP (for example, the area surrounded by the frame A in FIG. 6).

Even when the slit SLa is provided at the boundary between the dummy pixel area DMY and the outer circumference area OP as in the present embodiment, covering this slit SLa with the sealing layer SE1x suppresses the steep step shown in the comparative example of FIG. 14. Thus, the occurrence of coating defects in the resin layer RS1 can be suppressed.

### Third Embodiment

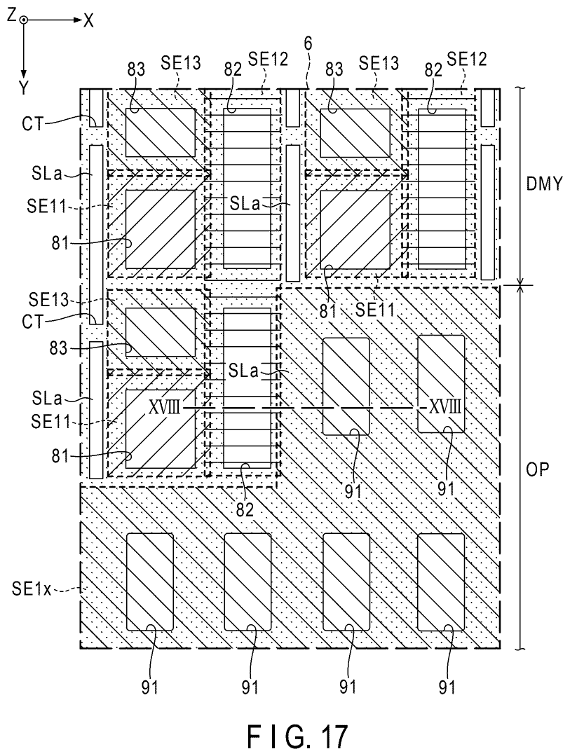

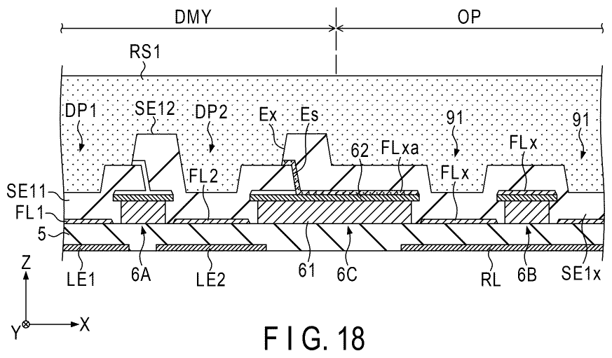

FIG. 17 is a schematic plan view showing a configuration according to the third embodiment. FIG. 18 is a schematic cross-sectional view of the dummy pixel area DMY and the outer circumference area OP along the XVIII-XVIII line of FIG. 17. These figures focus on the vicinity of the boundary between the dummy pixel area DMY and the outer circumference area OP in the same manner as FIG. 7 and FIG. 8.

In the same manner as the first embodiment, the slit SLa is not provided between the dummy pixel area DMY and the outer circumference area OP in the present embodiment. In contrast, in the same manner as the second embodiment, the end portion Ex of the sealing layer SE1x overlaps the end portion Es of the sealing layer SE12 in the Z-direction. This configuration also can the occurrence of the coating defects in the resin layer RS1 in the same manner as the above embodiments.

### Fourth Embodiment

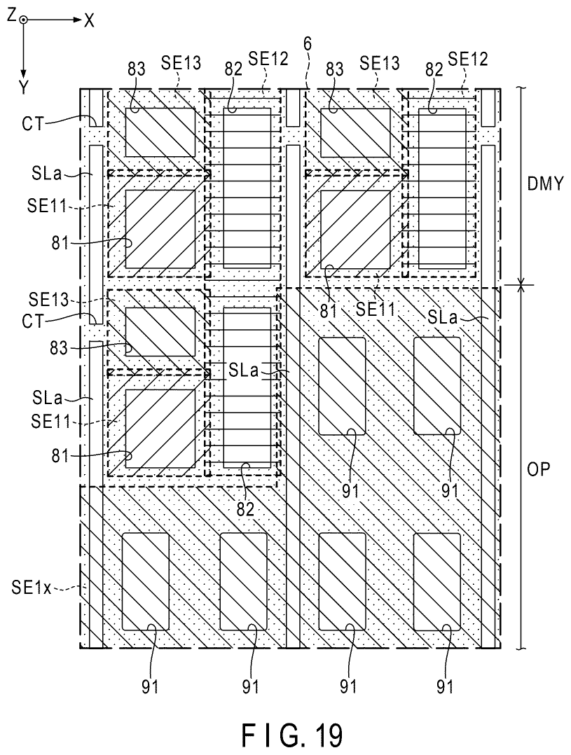

FIG. 19 is a schematic plan view showing a configuration according to the fourth embodiment. This figure focuses on the vicinity of the boundary between the dummy pixel area DMY and the outer circumference area OP in the same manner as FIG. 7.

In the present embodiment, the slit SLa extends across the dummy pixel area DMY and the outer circumference area OP. Each slit SLa passes between the apertures 91 adjacent to each other in the X-direction in the outer circumference area OP. At least one of the plurality of slits SLa may reach the end portion of the outer circumference area OP.

Each slit SLa in the outer circumference area OP is covered with the sealing layer SE1x. Also, as in the third embodiment, the slit SLa located at the boundary between the dummy pixel area DMY and the outer circumference area OP (the slit SLa located between the apertures 82 and 91 in the X-direction) are also covered with the sealing layer SE1x. This configuration also can the occurrence of the coating defects in the resin layer RS1 in the same manner as the above embodiments.

### Fifth Embodiment

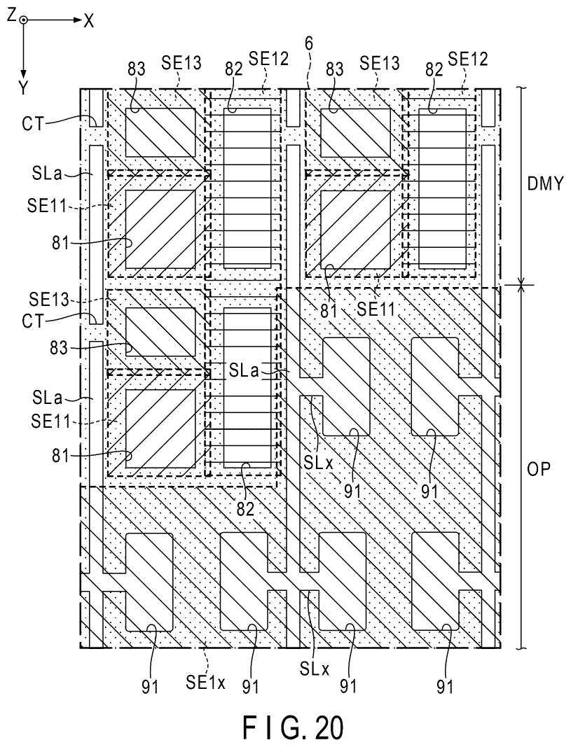

FIG. 20 is a schematic plan view showing a configuration according to the fifth embodiment. This figure focuses on the vicinity of the boundary between the dummy pixel area DMY and the outer circumference area OP in the same manner as FIG. 7.

In the same manner as the fourth embodiment, the slit SLa extends across the dummy pixel area DMY and the outer circumference area OP in the present embodiment. Furthermore, the aperture 91 and the slit SLa are connected to each other by a slit SLx extending in the X-direction in the present embodiment.

In the example of FIG. 20, the slit SLx intersects the slit SLa and is connected to two apertures 91. However, the slit SLx near the center of FIG. 20 is connected to the slit SLa to form a T-shape.

In the outer circumference area OP, the slit SLa, the slit SLx, and the aperture 91 are covered with the sealing layer SEx. This forms recess portions corresponding to the shapes of the slit SLa, the slit SLx, and the aperture 91 on the upper surface of the sealing layer SE1x. The droplets discharged in the formation of the resin layer RS1 can easily spread over the entire outer circumference area OP by moving through these recess portions.

### Sixth Embodiment

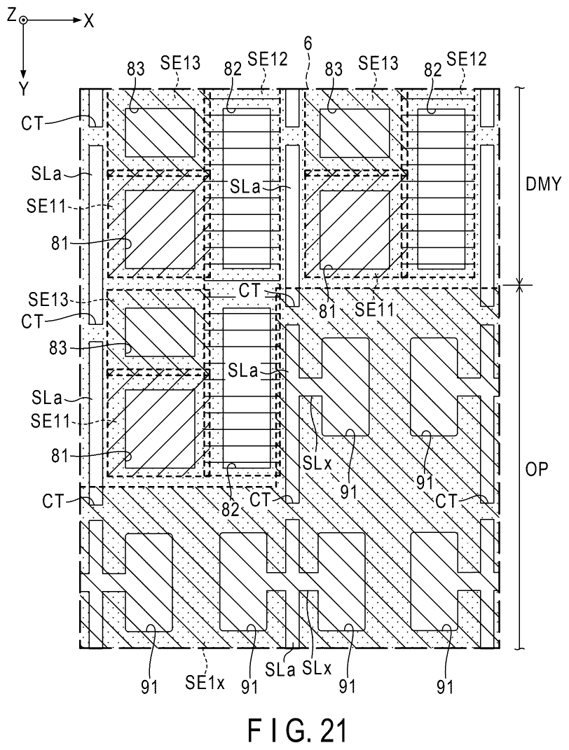

FIG. 21 is a schematic plan view showing a configuration according to the sixth embodiment. This figure focuses on the vicinity of the boundary between the dummy pixel area DMY and the outer circumference area OP in the same manner as FIG. 7.

In the same manner as the sixth embodiment, the slit SLa extends across the dummy pixel area DMY and the outer circumference area OP, and the aperture 91 and the slit SLa are connected to each other by the slit SLx extending in the X-direction in the present embodiment.

Further, in the present embodiment, the connection portion CT connecting portions into which the partition 6 is divided by the slit SLa is also provided in the outer circumference area OP. For example, the arrangement interval of the connecting portions CT in the Y-direction is the same in each of the display area DA, the dummy pixel area DMY, and the outer circumference area OP. At least one aperture 91 is connected to the slit SLa divided by the connecting portion CT. However, the slit SLa that is not connected to the aperture 91 may be provided in the outer circumference area OP.

The configurations disclosed in the first to sixth embodiments may be combined as appropriate. For example, the configuration of any of the embodiments may be applied to a part of the outer circumference area OP, and the configuration of another embodiment may be applied to another part.

In each of the above embodiments, the term “partition” includes various overhanging structures. Even if the overhanging structure has a shape different from the partition disclosed in each embodiment, the portion protruding laterally corresponds to the “upper portion” and the portion recessed below of the portion corresponds to the “lower portion”.

All of the display devices that can be implemented by a person of ordinary skill in the art through arbitrary design changes to the display device disclosed as each embodiment described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device, comprising:
a substrate having a display area for displaying images;
a plurality of pixels provided in the display area and each including a lower electrode, an upper electrode located above the lower electrode, and an organic layer located between the lower electrode and the upper electrode and emitting light based on application of voltage;
a dummy pixel area surrounding the display area and including a plurality of dummy pixels not displaying images; and
a partition provided in the display area, the dummy pixel area and an outer circumference area surrounding the dummy pixel area, the partition including a lower portion having conductivity and an upper portion having an end portion protruding relative to a side surface of the lower portion, wherein
the partition has a plurality of slits provided in the display area and the dummy pixel area, and
the slits are not provided at a boundary between the dummy pixel area and the outer circumference area.

2. The display device of claim 1, wherein
the partition has:
a plurality of first apertures provided in each of the plurality of pixels in the display area;
a plurality of second apertures provided in each of the plurality of dummy pixels in the dummy pixel area; and
a plurality of third apertures provided in the outer circumference area.

3. The display device of claim 2, wherein
the boundary between the dummy pixel area and the outer circumference area has a stepped shape,
the second aperture and the third aperture are arranged in a first direction in a part of the boundary, and
the plurality of slits extend in a second direction intersecting the first direction and are not provided between the second aperture and the third aperture arranged in the first direction.

4. The display device of claim 1, further comprising:
a first sealing layer formed of an inorganic insulating material and covering the plurality of pixels and the plurality of dummy pixels;
a second sealing layer formed of an inorganic insulating material and covering the outer circumference area; and
a resin layer covering the first sealing layer and the second sealing layer.

5. The display device of claim 4, wherein
the first sealing layer and the second sealing layer are spaced apart from each other at the boundary between the dummy pixel area and the outer circumference area.

6. The display device of claim 5, wherein
the resin layer covers the partition exposed from the first sealing layer and the second sealing layer at the boundary between the dummy pixel area and the outer circumference area.

7. The display device of claim 4, wherein
the first sealing layer and the second sealing layer overlap at the boundary between the dummy pixel area and the outer circumference area.

8. The display device of claim 1, wherein
the partition has a connection portion connecting portions divided by the slit in the display area and the dummy pixel area to one another.

9. The display device of claim 1, wherein
the display area, the dummy pixel area, and the outer circumference area have circular shapes.

10. A display device, comprising:
a substrate having a display area for displaying images;
a plurality of pixels provided in the display area and each including a lower electrode, an upper electrode located above the lower electrode, and an organic layer located between the lower electrode and the upper electrode and emitting light based on application of voltage;
a dummy pixel area surrounding the display area and including a plurality of dummy pixels not displaying images;
a partition provided in the display area, the dummy pixel area and an outer circumference area surrounding the dummy pixel area, the partition including a lower portion having conductivity and an upper portion having an end portion protruding relative to a side surface of the lower portion;
a first sealing layer formed of an inorganic insulating material and covering the plurality of pixels and the plurality of dummy pixels; and
a second sealing layer formed of an inorganic insulating material and covering the outer circumference area, wherein
the partition has a plurality of slits provided at least in the display area and the dummy pixel area,
at least one of the plurality of slits is located at a boundary between the dummy pixel area and the outer circumference area, and
the second sealing layer covers the slit located at the boundary.

11. The display device of claim 10, wherein
the first sealing layer and the second sealing layer overlap at the boundary between the dummy pixel area and the outer circumference area.

12. The display device of claim 10, wherein
at least one of the slits extends in the outer circumference area.

13. The display device of claim 12, wherein
the second sealing layer covers the slit located in the outer circumference area.

14. The display device of claim 12, wherein
the partition has:
a plurality of first apertures provided in each of the plurality of pixels in the display area;
a plurality of second apertures provided in each of the plurality of dummy pixels in the dummy pixel area; and
a plurality of third apertures provided in the outer circumference area.

15. The display device of claim 14, wherein
the boundary between the dummy pixel area and the outer circumference area has a stepped shape,
the second aperture and the third aperture are arranged in a first direction in a part of the boundary, and
at least one of the plurality of slits passes between the second aperture and the third aperture arranged in the first direction and extends in a second direction intersecting the first direction.

16. The display device of claim 15, wherein
at least one of the plurality of slits passes between the third apertures adjacent to each other in the first direction in the outer circumference area.

17. The display device of claim 16, wherein
at least one of the plurality of third apertures is connected to the slit located in the outer circumference area.

18. The display device of claim 16, wherein
the partition has a connection portion connecting portions divided by the slit located in the outer circumference area to one another.

19. The display device of claim 10, further comprising:
a resin layer covering the first sealing layer and the second sealing layer.

20. The display device of claim 10, wherein
the display area, the dummy pixel area, and the outer circumference area have circular shapes.
